(19) United States
(12) Patent Application Publication
(10) Pub. No.: US 2011/0041492 A1
(43) Pub. Date: Feb. 24, 2011

(54) Stirling engine with thermoelectric control

(76) Inventor: Daniel Maguire, Courtland Manor, NY (US)

Correspondence Address: IDEATION LAW, 2750 RIVERSIDE AVENUE, JACKSONVILLE, FL, 32205, US

(21) Appl. No.: 11/432,757

(22) Filed: May 10, 2006

(51) Int. Cl. F02G 1/04; F25B 21/02; H01L 35/34

(52) U.S. Cl. 60/520; 136/201; 62/3.3

(57) ABSTRACT

The present invention provides apparatus and methods for utilizing thermoelectric devices to control the operation of a Stirling type engine.

### FIELD OF THE INVENTION

This invention relates generally to gas displacement engines, such as Stirling type engines and devices which utilize thermal energy to power pistons through the expansion and contraction of gas contained in cylinders. In particular the present invention combines thermoelectric devices with gas displacement engines.

### BACKGROUND

Generally, a Stirling engine of the displacer type usually comprises a casing, a displacer arranged in the casing so as to slide, an expansion chamber and an operation chamber into which, and from which, an operation gas flows with the operation of the displacer, a power piston that is operated in response to a change in the pressure of the operation gas in the operation chamber, and an operation rod that is coupled to the displacer to operate the displacer at a predetermined timing. In the Stirling engine of the above displacer type, the power piston is operated in response to a change in the pressure in the operation chamber with the expansion and contraction as the operation gas is heated and cooled. Accordingly, it has been found that it is efficient to use an operation gas within the Stirling engine which has a small specific heat, such as hydrogen or helium, thereby improving the heat efficiency.

In some more recent designs of Stirling engines a free piston-type displacer is utilized and a gas spring, however, it is difficult to set a spring constant of the gas spring and, besides, the operation cycle is virtually determined by the spring constant of the gas spring. It is, therefore, difficult to make the operation cycle variable and, further, a starter mechanism must be separately provided. With the free piston-type displacer by utilizing the gravity, the direction of the casing is limited to the vertical direction only, and cannot be disposed laterally.

### SUMMARY

The present invention provides improved apparatus and methods for powering Stirling type engines by utilizing thermoelectric devices to transport thermal energy from one portion of the device to another portion of the device. The thermoelectric devices can also the used in conjunction with supplemental power sources and in some embodiments, an electrical generator can be included which charges batteries used to power the thermoelectric devices.

Various features and embodiments are further described in the following figures, drawings and claims.

### DESCRIPTION OF THE DRAWINGS

FIG. 1 illustrates a block diagram of some embodiments of the present invention.

FIG. 2 illustrates a block diagram of some embodiments of the present invention comprising a supplemental power source

FIG. 3 illustrates some embodiments of the present invention which include an inline Stirling type apparatus.

FIG. 4 illustrates some embodiments of the present invention which include an electrical generator which charges batteries used to power the thermoelectric devices.

### DETAILED DESCRIPTION

Overview

The present invention provides Stirling type devices with improved efficiency and responsiveness due to the use of thermoelectric devices which control the amount of thermal energy in one or more of the operation portion and the compression portion of the Stirling type device.

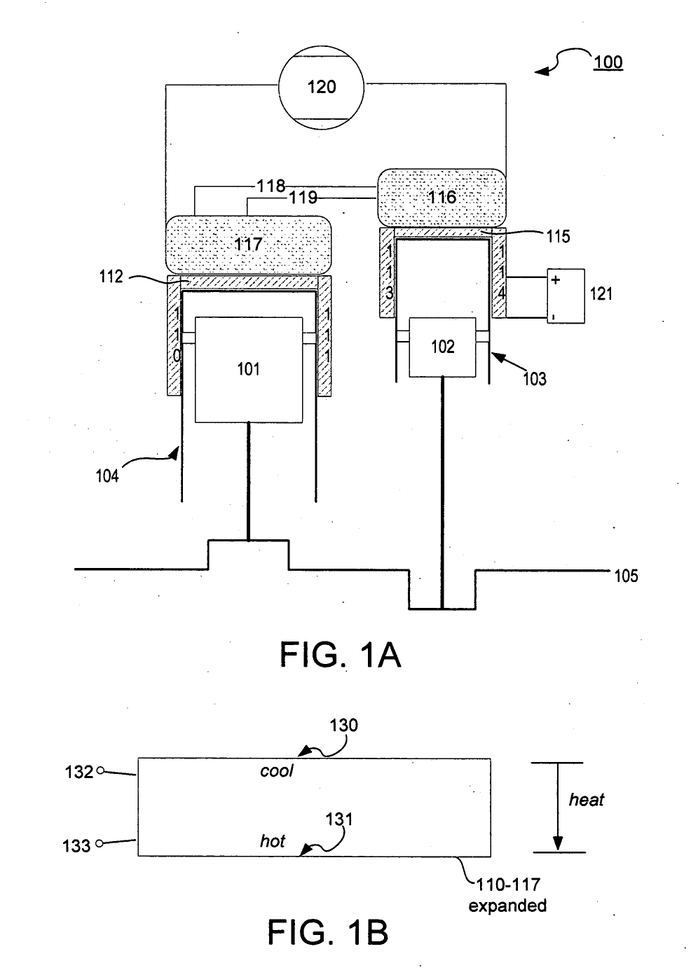

Referring now to FIG. 1, a Stirling type device can include an engine 100 with an external heat source that converts heat into driving power by continuous heating and cooling of a captive gas, such as helium. The Stirling type device operates on the principle that the gas expands when heated and contracts when cooled. Many different embodiments are known in the art, such as, for example: swashplate drives, rhombic drives, free piston engines, and others. One of the most basic designs includes a standard crankshaft 105 which drives two pistons 101-102 moving linearly within cylinders 103-104. In some embodiments the cylinders 103-104 are positioned ninety degrees from each other (not shown). Traditionally, heat was supplied to the expansion chamber via external combustion and a heat exchanger was used to convey heat away from the compression portion.

According to the present invention, thermal energy is controlled in one or both of the operation portion and the compression portion through the application of an electric current to one or more thermoelectric devices 110-117. Depending upon the current provided to the thermoelectric device, the thermoelectric device 110-117 may either provide heat through an increase in thermal energy, or cooling though a decrease of thermal energy.

Advances in the design of thermoelectric devices, and in particular the availability to have a device with thermal separation between a hot side and a cold side of the thermoelectric devices 110-117, have made it possible to utilize thermoelectric devices 110-117 to power the engine 100.

According to the present invention, thermoelectric devices 110-117 are positioned in thermal communication with the expansion portion 102 and the compression portion 103. Electrical current can be supplied to the thermoelectric devices 110-117 according to the demand being placed upon the engine 100. For example during an idling state and low current may be supplied to one or more of the thermoelectric devices 110-112 in thermal communication with the expansion portion 101 and a current may or may not be applied to the thermoelectric devices 113-115 in thermal communication with the compression portion 102.

During a period of engine 100 acceleration, or under a load, current can be applied to all of the thermoelectric devices 110-115 in order to provide heat to the expansion portion 101 of the engine 100 and cooling to the compression portion of the engine 100.

The thermoelectric devices 110-117 thereby control the level of thermal energy in the working gas, which moves back and forth between the compression portion and the expansion portion. This action of heating and cooling the helium changes its pressure and exerts a force on the pistons that drive the crankshaft. In some embodiments, the dual manipulation provided by the thermoelectric devices 110-117 which heated one portion of the working as in the expansion portion 101 and actively cooling the working gas in the compression portion 102, as compared with the ambient temperature, can increase the responsiveness of the engine 100.

Referring now to FIG. 1B, in general, the application of an electrical current across terminals 132-133 on the thermoelectric device will cause the thermoelectric device 110-117 to transfer thermal energy from a first portion 130 of the thermoelectric device 110-117, to a second portion of the thermoelectric device 131. Typically, each of the first portion 130 and the second portion 131, comprise an opposing surface of the thermoelectric device 110-117.

Referring now again to FIG. 1A, in some embodiments, the present invention also provides for heat energy to be removed from the compression portion 102 of the engine 100 via a heat exchange unit 116 and conveyed to the expansion portion via a second heat exchange unit 117. The action of highly efficient thermoelectric devices allows thermal energy from one portion of the device to another portion of the device. Therefore, an efficiency arises as the waste heat from the compression portion 102 is recycled to the expansion portion 101 of the Stirling engine 100.

Power to operate the thermoelectric devices 110-117 can be supplied by any known power source 121, including, for example: one or more batteries, a power supply, solar power, wind power, generator, or other source. Generators in particular will be discussed more fully below.

In still another aspect of the present invention, an electronic processor 120 can be utilized to control the operation of the Stirling engine 100 and the application of power to either, or both, of the expansion portion 101 and the compression portion 102. In addition, the processor 120 can monitor the speed of engine 120 rotation, the temperature of both the expansion portion 101 and the compression portion 102, and receive indications of what demand was being placed on the engine. To control the cyclical speed, the Stirling engine 100 according to the present invention adjusts the current that is applied across the thermoelectric devices 110-117.

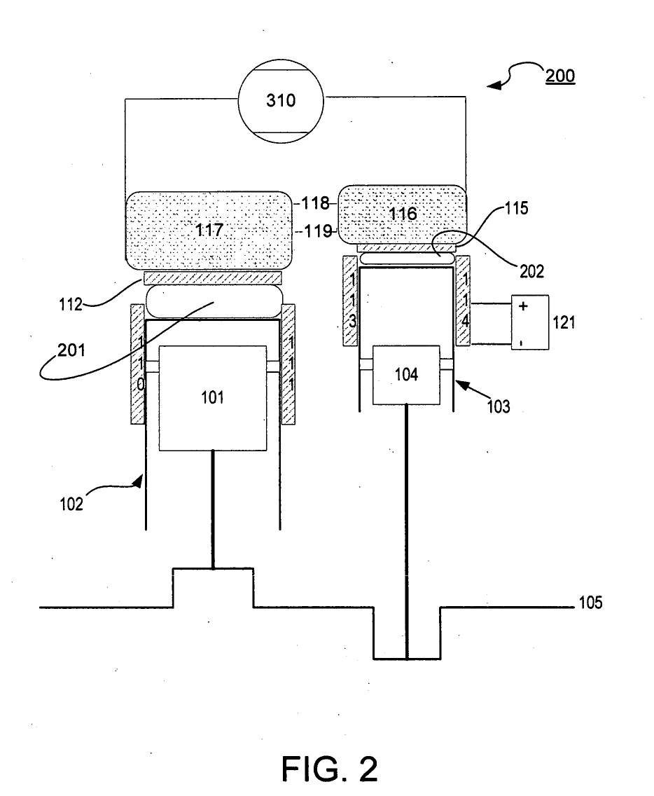

Referring now to FIG. 2, in some embodiments of the present invention, the Stirling engine 200 can include one or more of an auxiliary heat source 201 to provide supplemental heat to the expansion portion 101 and a heat exchange 202 to provide heat dissipation to the compression portion 102.

Supplemental heat can be supplied by any known means, such as, for example, external combustion, solar heat, electric elements, or other thermal energy source. Heater tubes within the combustion chamber can be connected to the cylinders, or other variations of the expansion portions 101 and compression portions 102 and to a water cooled heat exchanger.

Some embodiments with supplemental heat can operate the Stirling engine 200 at a predetermined operational level and the thermoelectric devices can be used in response to additional demand being placed upon the Stirling engine 200 such as an increased load, or an increased cycle speed, such as a rotation of the engine.

It is also within the scope of some embodiments of the present invention to harness power generated by the Stirling engine 100 or 200 during forced deceleration. For example, in some embodiments where the Stirling engine is mechanically coupled to a motor vehicle or a weighted flywheel, during deceleration of the engine, kinetic energy can be used to force rotation of the Stirling engine 100 or 200. During the forced rotation, compression of the working gas can generate heat which can be used to create a temperature differential across one or more thermoelectric devices 110-117. The temperature differential across the thermoelectric device 110-117 can generate an electric current which is stored in the batteries 120.

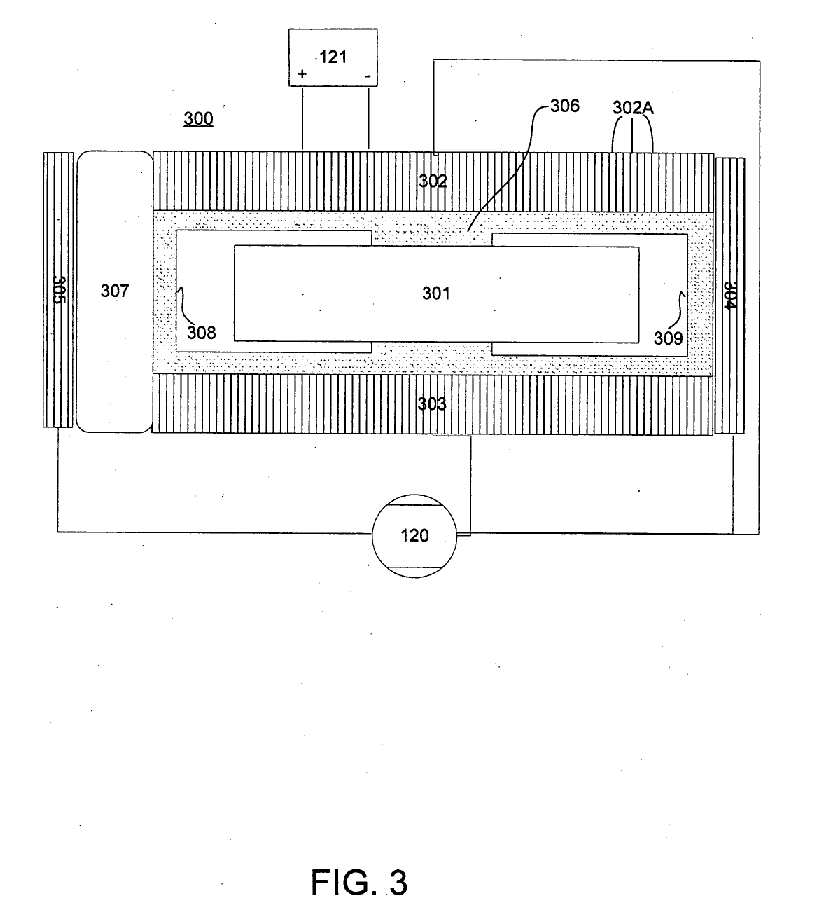

Referring now to FIG. 3, the present invention also includes thermoelectric enhancement of Stirling type apparatus 300 with the expansion portion 308 and the compression portion 309 arranged in a horizontal plane. Examples of inline Stirling devices are described in U.S. Pat. Nos. 6,843,057, 6,279,319 and 4,253,303, all of which are incorporated herein be reference in their entirety.

For example, a Stirling device 300 can include a free piston 301 which moves between the expansion portion 308 and the compression portion 309 in response to thermal energy differentials within the expansion portion 308 and the compression portion 309. Thermoelectric devices 302-305 are placed in thermal communication with the expansion portion 308 and the compression portion 309 and an electric current from a power source can be used to provide heat of cooling to either or both of the expansion portion 308 and the compression portion 309. Some embodiments can also include one roe more bellows which act as one or more of the expansion portion and the compression portion.

As illustrated in FIG. 3, a microprocessor 310 can be used to precisely control the application of thermal energy to specific areas of the expansion portion 308 and the compression portion 309, thereby increasing efficiency and also providing the ability to respond quickly to a demand for increased power or decreased power from the Stirling apparatus 300. Application of thermal energy to specific areas can be accomplished by using thermoelectric devices which include multiple discrete areas 302A each area individually connected to an electrical current supply.

The individual connection to a current supply allows each discrete area 302A to be controlled by the microprocessor to provide either heat or cooling. In addition, each area can be switched to a power generation mode, wherein current supplied to a discrete area 302A is turned off and that area 302A generates an electrical current in response to a temperature differential across it.

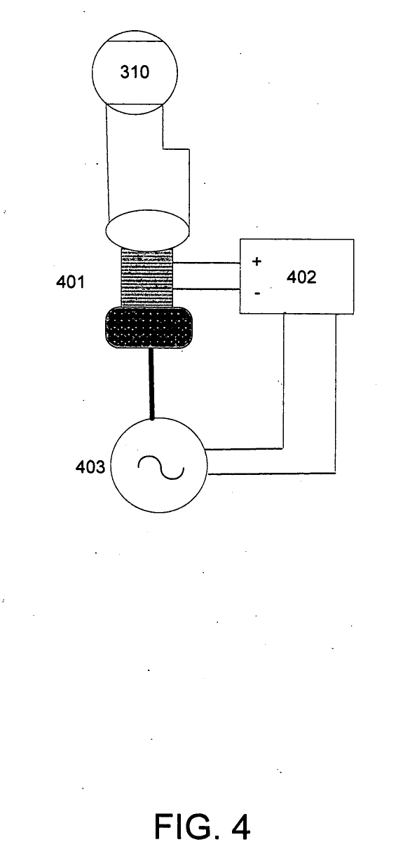

Referring now to FIG. 4, in some embodiments of the present invention, an electrical generator 403 can be mechanically linked to the Stirling apparatus 401 and generate electric current as the engine is operated. It is to be understood that a design of the generator will match the design of the Stirling apparatus 401. For example, a Stirling apparatus that include a crankshaft may be used to turn a rotating armature of a typical commercial type generator, while an inline Stirling apparatus 401 may be attached to permanent magnets to generate electricity from its linear motion.

As the Stirling apparatus 401 operates, it can power the generator 403 and increase its cyclical speed or decrease its speed according to a demand placed upon the generator. A microprocessor 310 can monitor the demand placed upon the generator 403 and increase or decrease the electrical current to thermoelectric devices used to control operation of the Stirling apparatus 401 as described above, in relation to the demand placed upon the generator.

In addition, a battery contingent 402, which may include an array of batteries 402, can also be electrically connected to the generator such that the generator can charge the battery 402 during its operation. This design can be particularly useful for example, in those embodiments that include a supplementary power source 201-202 such as solar energy, geothermal energy, wind energy and the like which cannot be easily regulated to respond on demand (hereinafter “passive”). The passive supplementary power can be used to operate the Stirling apparatus 401 when the supplemental power is available and the Stirling apparatus can charge the battery 402 during this passive operation. The battery 402 can then be used to respond to a demand for more power than the passive power source can provide.

Those schooled in the art will understand that any one supplemental power source 201-202 does not preclude additional supplemental power sources 201-202. Accordingly, one or more of solar power, geothermal power and wind power, can also be combined with an external combustion power source, or other power source to operate the Stirling apparatus 401. Conventional means, such as piped water or other heat exchanging liquid can be used to convey thermal energy to and from and external power source according to various applications. In addition, it is to be understood that the supplemental power sources can be converted to electricity and the electric power conveyed to the thermoelectric devices or to a heating element to provide thermal energy to a Stirling type engine. Also, although power sources 201-202 other than the thermoelectric devices 110-117 are referred to herein as supplemental power sources, this should not limit the scope of the present invention to mean that the supplemental power sources cannot provide more thermal energy during any given period of operation of a Stirling type engine. Supplemental is only meant to distinguish from thermal energy provided by thermoelectric devices, not a magnitude of thermal power provided.

### Thermoelectric Devices

As referred to herein, a thermoelectric device 110-117 includes any device that can respond to the application of electric power, such as a direct current (DC) voltage, by transferring thermal energy from a first portion to a second portion. An example of a thermoelectric device includes as a Peltier Crystal of dissimilar materials which is capable of controllably transferring thermal energy from one portion of the device to another portion of the device or alternatively, creating a voltage when a temperature differential is applied across the dissimilar portions.

Additional examples of thermoelectric devices 110-117 can include devices with thermal separation characteristics which provide for the transfer of thermal energy through the thermoelectric device under power, but prevent simple conduction of heat back through the device. Some examples of thermoelectric devices 110-117 are described in U.S. Pat. No. 6,906,449 and U.S. Patent Application 2004/0050415. Other embodiments can also include devices 110-117 capable of acting as a thermal diode which controllably transfer thermal energy in one direction from one portion of the thermal diodic device to another portion of the diodic device and to resist the transfer of thermal energy in the opposing direction.

In addition, in some embodiments, some thermoelectric devices 110-117 utilized in the present invention include the ability to generate an electrical current as a temperature differential is applied across different portions of the respective devices 110-117.

Referring now to FIG. 1-3, in some embodiments of the present invention, one or more layers of thermoelectric devices 110-117 can be combined to increase the power generation capacity or increase the efficiency to transfer thermal energy energy, according to a particular application. Multiple layers thermoelectric devices 110-117 can also be arranged in thermal and electrical series, such that the temperature differential can be controlled across any particular thermoelectric devices 110-117 or set of thermoelectric devices 110-117. Control of the temperature differential can be useful, for example, to limit any adverse physical effects, such as expansion or contraction that may cause cracking between layers that would otherwise have larger temperature differential. The thermal energy differential of a particular thermoelectric device 110-117, can be controlled by controlling a voltage applied across the particular thermoelectric device 110-117.

A number of embodiments of the present invention have been described. Nevertheless, it will be understood that various modifications may be made without departing from the spirit and scope of the invention. For example, some embodiments can also include permanent magnets attached to moving components of the Stirling apparatus which generate an electrical current while the Engine is operating and various methods or equipment may be used to implement the steps described herein. In addition, various casings and packaging can also be included in order to better adapt a thermoelectric devices to the environment of a Stirling apparatus according to a specific application. Accordingly, other embodiments are within the scope of the following claims.

What is claimed is:

1. An apparatus incorporating the general principles of the Stirling cycle, the apparatus comprising:
a gas enclosure containing an entrapped gas, said gas enclosure including internally thereof a variable volume expansion space and a variable volume compression space;
one or more displacer means movably contained within said gas enclosure for moving said gaseous medium back and forth between said expansion space and said compression space;
one or more power means movably contained within said gas enclosure and responsive to an increase in thermal energy in a portion of the entrapped gas to linearly move under load;
at least one thermoelectric device with thermal separation characteristics for controlling an amount of thermal energy in the portion of entrapped gas to which the power means is responsive by moving linearly under load.

2. The apparatus of claim 1 wherein the power means comprises a piston.

3. The apparatus of claim 1 wherein the power means comprises a bellows.

4. The apparatus of claim 1 wherein the displacement means comprises a piston.

5. The apparatus of claim 1 wherein the power means comprises a piston.

6. The apparatus of claim 1 additionally comprising:
a first thermoelectric device that can be made operative to apply thermal energy to the entrapped gas; and
a second thermoelectric device that can be made operative to remove thermal energy from the entrapped gas.

7. The apparatus of claim 6 wherein the power means comprises a power piston and the displacement means comprises a displacement piston and the apparatus additionally comprises:
a first connecting rod mechanically linking the power piston to a crankshaft; and
a second connecting rod mechanically linking the displacement piston to the crankshaft.

8. The apparatus of claim 6 wherein at least one of the first thermoelectric device and the second thermoelectric device generate thermal separation characteristics.

8. The apparatus of claim 7 wherein the thermal separation characteristics can be generated via the application of a direct current voltage across the thermoelectric device.

9. The apparatus of claim 1 wherein a temperature differential can be applied across the thermoelectric device to cause a voltage to be generated.

10. The apparatus of claim 1 additionally comprising a processor operatively connected to the at least one thermoelectric device and to a power source to control the application of electric power across the at least one thermoelectric device.

11. The apparatus of claim 1 additionally comprising a processor operatively connected to the at least one thermoelectric device to control the generation of electric power by the thermoelectric device.

12. The apparatus of claim 11 additionally comprising an electrical storage device to store the electrical energy generated.

13. The apparatus of claim 12 wherein the electrical storage device is a battery.

14. The apparatus of claim 6 additionally comprising a means to convey thermal energy from the second thermoelectric device to the first thermoelectric device.

15. An apparatus which operates on the Stirling cycle and a thermoelectric device for facilitating thermal energy differentials between portions of the apparatus:
the apparatus which operates on the Stirling cycle comprising an atmospherically contained expansion area and an atmospherically contained compression area, wherein the thermoelectric device is operative to cause a sufficient thermal energy delta between the expansion area and the compression area to operate the apparatus through a Stirling cycle; and
the thermoelectric device comprising:
an electrically and thermally conductive electric charge emitter surface;
an electrically and thermally conductive electric charge collector surface positioned to receive electrons from the emitter; and
a thermally and electrically nonconductive space between said emitter and said collector.

16. The thermoelectric device of claim 15 wherein the electric charge emitter surface is about 5 nanometers or less from the collector surface.

17. A method for operating a Stirling type engine, the method comprising the steps of:
connecting one or more thermoelectric devices in thermal communication with one or more of: an expansion portion and a compression portion of the Stirling type engine; and
applying an electrical current to the one or more thermoelectric devices to communicate thermal energy to the one or more of: an expansion portion and a compression portion of the Stirling type engine.

18. The method of claim 17 additionally comprising the steps of generating electrical power with an electrical generator linked to the Stirling type engine and charging one or more batteries in electrical communication with the one or more thermoelectric devices.

19. The method of claim 18 additionally comprising the step of supplying thermal energy to the one or more of the expansion portion and the compression portion with a supplemental power source.

20. The method of claim 19 wherein the supplemental power source comprises one or more of: solar energy, geothermal energy, wind powered energy, and external combustion.
